(19) United States
(12) Patent Application Publication
(10) Pub. No.: US 2013/0322020 A1
(43) Pub. Date: Dec. 5, 2013

(54) ELECTRONIC DEVICE AND PROTECTIVE ELEMENT THEREFOR FOR USE IN EXPLOSION ENDANGERED AREAS

(71) Applicants: Winfried Mayer, Buch (DE); Roland Grozinger, Neuenburg (DE)

(72) Inventors: Winfried Mayer, Buch (DE); Roland Grozinger, Neuenburg (DE)

(73) Assignee: Endress +Hauser Fmbh + Co. KG, Maulburg (DE)

(21) Appl. No.: 13/985,067

(22) PCT Filed: Feb. 10, 2012
(86) PCT No.: PCT/EP2012/052298

§ 371 Date: Aug. 13, 2013

(30) Foreign Application Priority Data
Feb. 14, 2011 (DE) 10 2011 004 061.7

(51) Int. Cl. H05K 7/20; H05K 9/00

(52) U.S. Cl. CPC H05K 7/2039; H05K 9/00
USPC 361/713

(57) ABSTRACT

An electronic device for use in explosion endangered areas, comprising a superordinated electronic unit, a plurality of electronic components connected to the superordinated unit and supplied with energy by the superordinated unit, and a protective element installed in a number of connection lines for connecting respective ones of the components to the superordinated unit. In the case of a malfunctioning of one of the components, a space saving, safe conversion of the power available via the superordinated unit into heat occurs. The protective element comprises an electrically insulating, heat conductive, base body, and a number of resistors applied on the base body and corresponding to the number of connection lines, wherein each of the resistors is provided an input and output side with a connection, via which it is connected to a respective one of the connection lines.

The invention relates to an electronic device for use in explosion endangered areas. The electronic device has a superordinated electronic unit and a plurality of electronic components connected to the superordinated unit and supplied with energy by such. The invention relates further to a protective element, with which, in the case of a malfunction of a component, power provided by the superordinated unit is safely transformable into heat.

A large number of electronic devices, especially measuring devices, such as e.g. pressure-, temperature-, flow or fill level measuring devices, are applied in industrial measurements technology. These have, as a rule, an energy supplied, superordinated electronic unit, to which are connected a number of electronic components supplied with energy via the superordinated unit, e.g. electronic components, such as sensors, measuring-, control- and/or evaluation circuits or signal processors.

In fields of use in which danger of explosion is present, strict safety specifications are applied. In such case, especially spark formation is to be prevented, since such could, in given cases, trigger an explosion. Correspondingly, the power available to the superordinated unit is today regularly limited by corresponding electrical current and voltage limiting, protective circuits to a predetermined maximum power, e.g. to 1 Watt. Moreover, it must be assured in the device that the power provided to the components by the superordinated unit can also not cause a spark in the case of a malfunction. This is accomplished today usually by a safe conversion of the power into heat. This safe conversion of the electrical power provided to the respective component by the superordinated electronic unit in the case of a malfunction of the component into heat is accomplished in such a manner that explosive media located in the environment, such as e.g. gases or dusts, cannot be ignited.

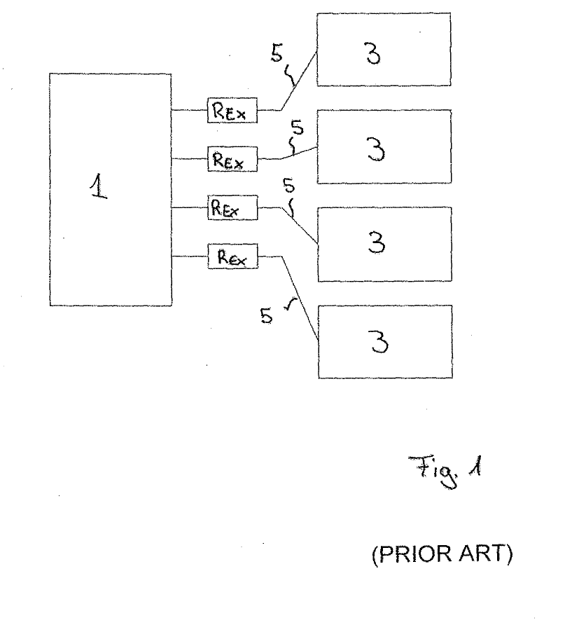

This requirement is today usually fulfilled in the manner shown in FIG. 1, wherein the superordinated unit 1 is connected to a number of subordinated components 3, and in each of the connection lines 5 connecting the superordinated unit 1 with the components 3, a so-called explosion protection resistor R_{Ex} is inserted. In such case, each explosion protection resistor R_{Ex} is made sufficiently large that it is able in the case of malfunction to convert the entire power available from the superordinated unit 1 into heat. Size and form of construction of each individual explosion protection resistor R_{Ex} are, in such case, to be designed in such a manner that the explosion protection resistor REX does not overheat, when, e.g. due to a short-circuit in the component 3 connected thereto, the entire power available from the superordinated unit 1 is converted into heat. As a function of the maximum power available in the superordinated unit 1, for this, as a rule, explosion protection resistors R_{Ex} with very large mechanical dimensions are required, in order to assure the absorbing and safe disposal of the heat.

This leads due to the required size of the explosion protection resistors R_{Ex}, especially in the case of devices with many subordinated components 3, to a considerable space requirement and conflicts with miniaturization and cost optimization.

It is an object of the invention to provide a protective element and a device of the initially stated type equipped with such a protective element, with which, in the case of malfunction of a component, in place saving manner, a safe conversion of the power available from the superordinated unit into heat is assured.

For this, the invention resides in an electronic device for use in explosion endangered areas, comprising
a superordinated electronic unit,
a plurality of electronic components connected to the superordinated unit and supplied with energy by the superordinated unit, and
a protective element installed in a number of connection lines for connecting respective ones of the components to the superordinated unit and comprising
   an electrically insulating, heat conductive, base body, and
   a number of resistors applied on the base body and corresponding to the number of connection lines, wherein each of the resistors is provided input and output side with a connection, via which it is inserted in a respective one of the connection lines.

In a preferred embodiment, the base body comprises a ceramic, especially aluminum nitride (AlN).

In an additional embodiment, the resistors are thin film resistors, especially thin film resistors of TaNi or NiCr.

In a first further development, there is applied on a side of the base body lying opposite that bearing the resistors a heat conducting layer, especially a metal coating.

In an additional further development of the first further development
the protective element lies with the side of the base body having the heat conducting layer on a circuit board, and
the circuit board has a cavity in a region covered by the heat conducting layer.

In a second further development
the protective element is arranged on a circuit board,
the side of the base body bearing the resistors faces the circuit board, and
the circuit board and the protective element are spaced from one another by spacers.

In a further development of the second further development, an electrically insulating heat conducting element is arranged between the circuit board and the protective element.

In a further development of the second further development, the spacers are the connections of the resistors and protrude out from a plane of the resistors on the side of the base body bearing the resistors in a direction facing away from the base body.

In a third further development, a side of the protective element bearing the resistors is coated with an electrically insulating, heat conducting layer, especially a lacquer or a potting compound.

Moreover, the invention resides in a protective element for electrically connecting a superordinated electronic unit to a number of electronic components supplied with energy via the superordinated unit, comprising
an electrically insulating, heat conductive, base body,
a number of mutually parallel resistors applied on the base body and corresponding to the number of components, wherein each of the resistors is connectable via an input side connection to the unit and via an output side connection to one of the components.

The invention and other advantages will now be explained in greater detail based on the figures of the drawing, in which two examples of embodiments are presented; equal elements are provided in the figures with equal reference characters. The figures of the drawing show as follows:

FIG. 1 a block diagram of a device according to the state of the art;

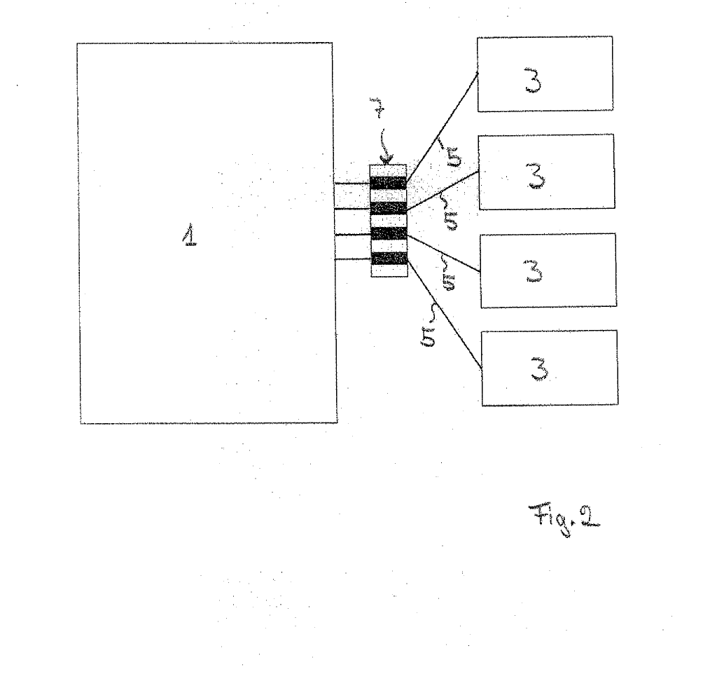

FIG. 2 a block diagram of a device of the invention;

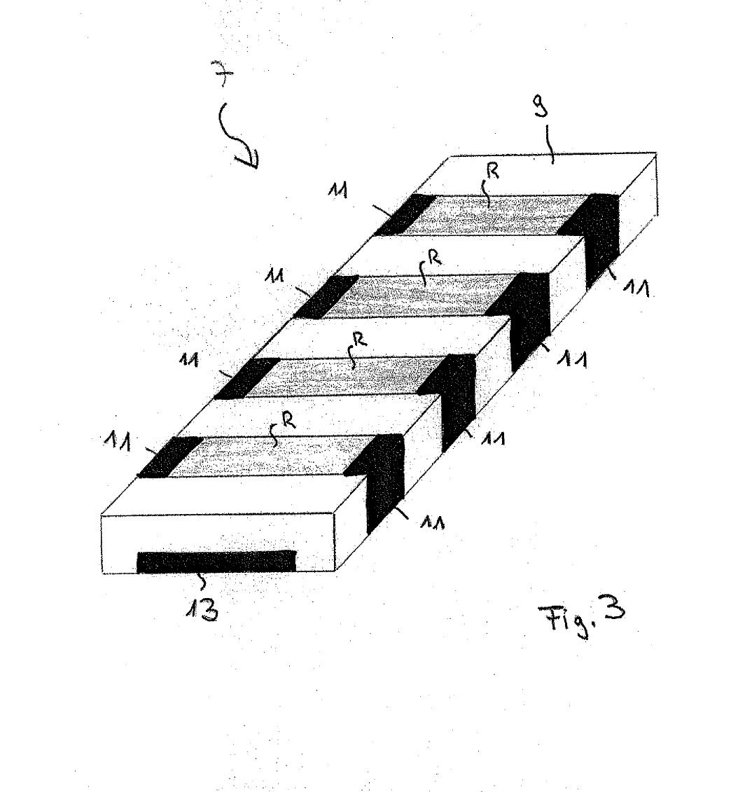

FIG. 3 a view of a first variant of the protective element of the invention;

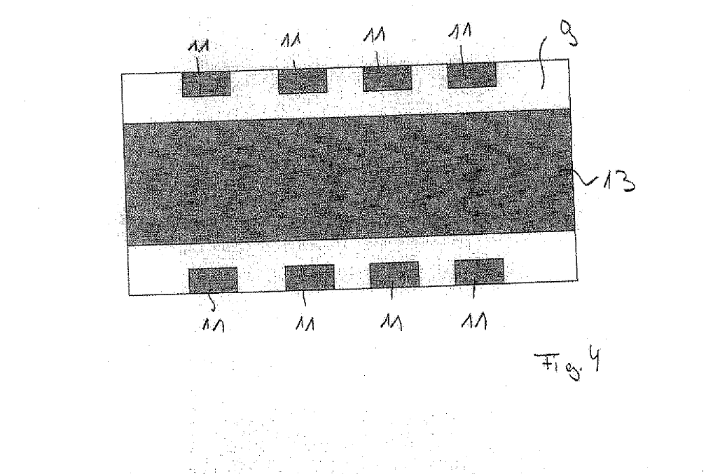

FIG. 4 an underside of the protective element of FIG. 3;

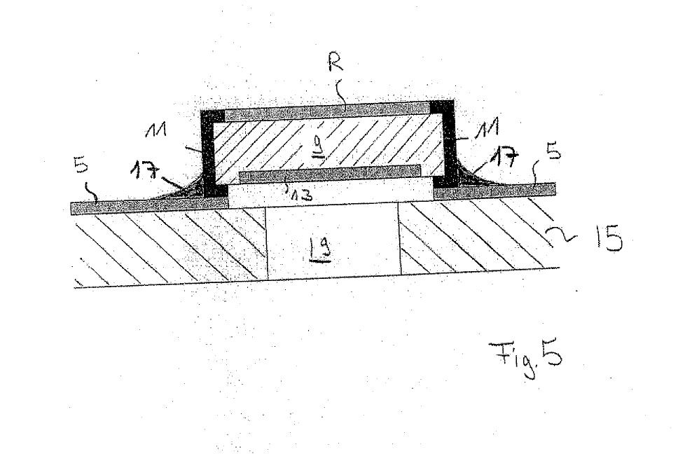

FIG. 5 a sectional drawing of the protective element of FIG. 3 on a circuit board;

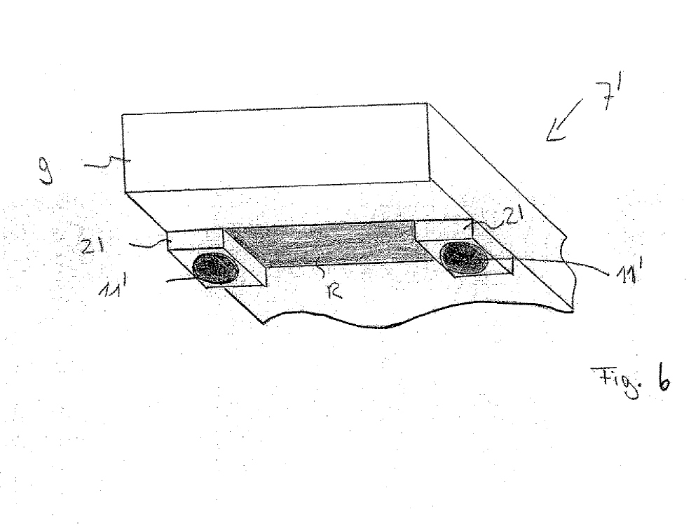

FIG. 6 a partial view of a second variant of the protective element of the invention; and

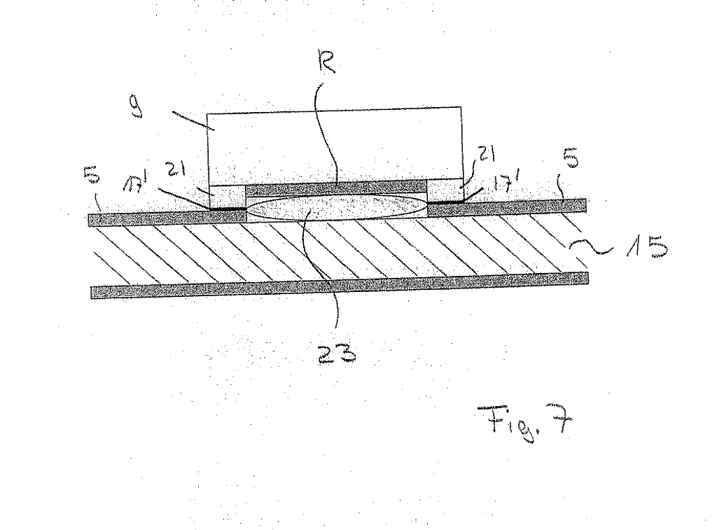

FIG. 7 a sectional drawing of the protective element of FIG. 6 on a circuit board.

FIG. 2 shows a block diagram of an electronic device of the invention for use in explosion endangered areas. It includes a single superordinated electronic unit 1, to which a plurality of subordinated electronic components 3 are connected. Each of the components 3 is connected to the superordinated unit 1 via a connection line 5 and supplied with energy by the superordinated unit 1.

According to the invention, a protective element 7 is provided inserted in a number of connection lines 5 connecting respective ones of the components 3 with the superordinated unit 1. In the illustrated example of an embodiment, all components 3 are connected with the superordinated unit 1 via the shown protective element 7. Alternatively, however, also a number of groups of components can, in each case, be connected to the superordinated unit 1 via an individual protective element inserted into the connection lines of all components of the respective group.

FIG. 3 shows a first variant of a protective element 7 of the invention. It includes a base body 9 of an electrically insulating, heat conductive material, such as e.g. a ceramic. A ceramic material especially suitable due to its high thermal conductivity in the order of magnitude of 200 W/mK is e.g. aluminum nitride (AlN).

Applied on the base body 9 are a number of resistors R corresponding to the number of connection lines 5 leading across the protective element 7. The resistors R are preferably thin film resistors, especially thin film resistors of TaNi or NiCr.

Each resistor R is provided input and output side with a connection 11 for one of the connection lines 5. In the variant illustrated in FIG. 3, the resistors R are embodied as strip shaped, surface resistors, which extend, mutually parallel, transversely across an upper side of the base body 9. The connections 11 provided on the input and output sides are, for example, SMD solder connections arranged on oppositely lying, side surfaces of the base body 9, each connected with a respective end of a resistor R on the upper side of the base body 9.

In the case of malfunction of one or more components 3 connected via the protective element 7 to the superordinated unit 1, the energy available via the superordinated unit 1 is to be converted safely into heat. Since only one superordinated unit 1 is present, this energy also is present only once, independently of how many components 3 are connected to the superordinated unit 1 via the protective element 7. Other than in the case of the initially described state of the art, in the case of which each individual protective resistor REx must be able to convert the energy available from the superordinated unit 1 in the case of malfunction safely into heat, here the one-time conversion by the protective element 7 suffices, independently of the number of components 3 connected thereacross.

A malfunction of one of the components 3 leads to an increased electrical current through that resistor R of the protective element 7 located in the connection line 5 of such component 3. The heat released in such case is absorbed by the base body 9 and removed via the base body 9. In such case, the preferably high thermal conductivity of the base body 9 effects an approximately equally distributed warming of the base body 9 and therewith an effective, large surface, heat removal. Due to the only once present energy to be converted into heat, a simultaneously occurring malfunctioning of two or more components 3 does not lead to a higher heat development on the protective element 7. Thus, even in the case of simultaneous malfunctioning of a plurality of components 3, a single base body 9 suffices for safe heat conversion. According to the invention, consequently, only a single, centrally arranged, base body 9 is required for the connection of a number of components 3 to a superordinated unit 1. In this way, considerable space is saved, which is then available for miniaturization of the device, for other components or for other uses.

For improving the heat removal, a heat conducting layer 13, especially a metal coating, can be applied on a side of the base body 9 lying opposite the resistors R. As shown in FIGS. 3 and 4, the heat conducting layer 13 can be placed in a corresponding cavity in the base body 9. The presence of heat conducting layer 13 makes it possible either to increase the amount of heat convertible by the protective element 7, and therewith the energy available via the superordinated unit 1, or, in the case of equal energy available via the superordinated unit 1, to reduce the dimensions of the base body 9.

The protective element 7 is, for example, such as shown in FIG. 5, arranged on a circuit board 15, on whose upper side the connection lines 5 between superordinated unit 1 and the components 3 are applied. The protective element 7 is inserted into the connection lines 5. The connection lines 5 lead, in each case, to resistor connections 11 arranged on the oppositely lying sides of the base body 9 for the resistors R. Electrical continuity between the respective connection lines and connections 11 is provided, for example, via soldered connections 17. Preferably, these soldered connections 17 serve at the same time also for mechanical securement of the protective element 7 to the circuit board 15.

For additionally improving the heat removal in the case of a malfunction, circuit board 15 has in its region covered by the protective element 7 a cavity 19, via which heat is removed through the circuit board 15. This measure leads to a very effective heat removal, especially in combination with a heat conducting layer 13 provided on the side of the base body 9 facing the circuit board 15. Alternatively, the heat conducting layer 13 can, however, also be applied, respectively soldered, to a cooling surface (not shown) provided on the circuit board 15.

FIG. 6 shows a section of an additional variant of the protective element 7′ of the invention. Due to the similarity to the earlier described variant, here only the differences are explained in greater detail. In contrast to the previously described variant, the resistors R and their connections 11′ are arranged here on one and the same side of the base body 9. In this way, spacers 21 between circuit board 15 and base body 9 make it possible to mount the protective element 7′—such as shown in FIG. 7—in such a manner on the circuit board 15 that the resistors R are located on the side of the base body 9 facing the circuit board 15.

Spacers 21 are preferably formed by the connections 11′ of the resistors R, which, for this, protrude out on the side of the base body 9 bearing the resistors R from a plane of the resistors R in a direction facing away from the base body 9. The connections 11′ are also here preferably connected via soldered connections 17′ to the connection lines 5 extending on the circuit board 15 to the protective element 7′.

Exactly as in the case of the example of an embodiment illustrated in FIG. 5, here also, in the region of the circuit board 15 covered by the protective element 7′, a cavity (here not shown) for improving the heat removal can be provided through the circuit board 15.

Alternatively, an electrically insulating, heat conducting element 23 can be arranged between the circuit board 15 and the protective element 7′ for improving the heat removal.

Moreover, preferably at least the side of the protective element 7, respectively 7′, bearing the resistors R is coated with an electrically insulating, heat conducting layer, especially a lacquer or a potting compound. This heat conducting layer offers, on the one hand, the advantage that it promotes and accelerates the uniform distribution of the local heat evolution in the region of individual resistors R over the base body 9. On the other hand, it improves the insulation of the individual resistors R from one another given by the separation between the individual resistors R, and contributes therewith to increasing the breakdown voltage.

1 superordinated unit

3 component

5 connection line

7 protective element

7′ protective element

9 base body

11 connection

11′ connection

13 heat conducting layer

15 circuit board

17 soldered connection

19 cavity in the circuit board

21 spacers

23 heat conducting element

1-10. (canceled)

11. An electronic device for use in explosion endangered areas, comprising:
a superordinated electronic unit;
a plurality of electronic components connected by a connecting line to said superordinated unit and supplied with energy by said superordinated unit; and
a protective element installed in a number of connection lines for connecting respective ones of the components to said superordinated unit, said protective element comprising:
an electrically insulating, heat conductive, base body; and
a number of resistors applied on said base body and corresponding to the number of connection lines, wherein each of said resistors is provided on their input and output side with a connection, via which it is inserted in a respective one of said connection lines.

12. The electronic device as claimed in claim 11, wherein:
said base body comprises a ceramic, especially aluminum nitride (AlN).

13. The electronic device as claimed in claim 11, wherein:
said resistors are thin film resistors, especially thin film resistors of TaNi or NiCr.

14. The electronic device as claimed in claim 11, wherein:
there is applied on a side of said base body lying opposite that bearing said resistors a heat conducting layer, especially a metal coating.

15. The electronic device as claimed in claim 14, wherein:
said protective element lies with the side of said base body having said heat conducting layer on a circuit board; and
said circuit board has a cavity in a region covered by said heat conducting layer.

16. The electronic device as claimed in claim 11, wherein:
said protective element is arranged on a circuit board;
the side of said base body bearing said resistors faces said circuit board; and
said circuit board and said protective element are spaced from one another by spacers.

17. The electronic device as claimed in claim 16, wherein:
at least one electrically insulating, heat conducting element is arranged between said circuit board and said protective element.

18. The electronic device as claimed in claim 16, wherein:
said spacers are the connections of said resistors and protrude out from a plane of said resistors on the side of said base body bearing said resistors in a direction facing away from said base body.

19. The electronic device as claimed in claim 11, wherein:
a side of said protective element bearing said resistors is coated with an electrically insulating, heat conducting layer, especially a lacquer or a potting compound.

20. A protective element for electrically connecting a superordinated electronic unit to a number of electronic components supplied with energy via the superordinated unit, comprising:
an electrically insulating, heat conductive, base body; and
a number of resistors applied on said base body and corresponding to the number of said electronic components, wherein:
each of said resistors is connectable via an input side connection to said superordinated electronic unit and via an output side connection to one of said electronic components.
